(19) United States
(12) Patent Application Publication
(10) Pub. No.: US 2012/0073652 A1
(43) Pub. Date: Mar. 29, 2012

(54) TRANSPARENT COMPOSITE STRUCTURE INTEGRATING A PHOTOVOLTAIC CELL

(75) Inventors: Beatrice Mottelet, Compiegne (FR); Adele Verrat-Debailleul, Villers Sur Coudun (FR)

(73) Assignee: SAINT-GOBAIN GLASS FRANCE, Courbevoie (FR)

(21) Appl. No.: 13/263,264

(22) PCT Filed: Apr. 2, 2010
(86) PCT No.: PCT/FR10/50642

§ 371 Date: Dec. 1, 2011

(30) Foreign Application Priority Data
Apr. 9, 2009 (FR) 0952317

(51) Int. Cl. H01L 31/0203; H01L 31/18; H01L 31/0264

(52) U.S. Cl. 136/258; 136/259; 136/261; 136/262; 136/260; 438/66; 257/E31.117

(57) ABSTRACT

The invention relates to
a composite structure comprising a photovoltaic cell adhering to an injected polymer (1), in which the photovoltaic cell exhibits an active face (2) adhering to a base (3), characterized in that the photovoltaic cell is continuous and its face directed away from the injected polymer (1) is caused to adhere to an encapsulating polymer (4) with a linear thermal expansion coefficient which does not differ by more than 65% from that of the injected polymer (1) and with a minimum melting point which allows it to withstand the injection of the latter and which promotes adhesion to the injected polymer (1), or in that the photovoltaic cell is openwork;
a simple or multiple and monolithic or laminated window comprising such a structure.

The present invention relates to rendering a photovoltaic cell integral with a sheet of injectable polymer, in particular transparent polymer, such as polycarbonate.

The injection of the polycarbonate is carried out at a temperature of approximately 305° C.

Moreover, a photovoltaic cell is, for example, composed of an thin active face of silicon rendered integral with a base made of metal or of plastic.

The photovoltaic cell is flexible or rigid. Where it is placed in a polycarbonate injection mold, a warping of the combination during the cooling from 305° C., for example, to ambient temperature is often observed.

This warping is due to the differential thermal expansion of the base and active face of the photovoltaic cell, on the one hand, and of the injected material, on the other hand, and to the effect of the shrinkage of the latter.

The inventors set themselves the task of obtaining products of the abovementioned type while guaranteeing the maintenance of the flat or domed geometry thereof, given by the polycarbonate or equivalent injection mold, after cooling, the integrity of the photovoltaic cell on cooling and under living conditions, and a good durability.

To this end, a subject matter of the invention is a composite structure comprising a photovoltaic cell adhering to an injected polymer, in which the photovoltaic cell exhibits an active face adhering to a base, characterized in that the photovoltaic cell is continuous and its face directed away from the injected polymer is caused to adhere to an encapsulating polymer with a linear thermal expansion coefficient which does not differ by more than 65% from that of the injected polymer and, with a minimum melting point which allows it to withstand the injection of the latter and which promotes adhesion to the injected polymer, or in that the photovoltaic cell is openwork.

The photovoltaic cell is described as continuous when it exhibits an unbroken surface devoid of holes or discontinuities.

In contrast, an openwork photovoltaic cell refers here to a noncontinuous surface, comprising holes, such as a grid, or to a combination of several small unjoined cells.

By thus limiting the differential expansion of the photovoltaic cell and of the injected polymer during the cooling of the latter following the injection, the maintenance of the final geometry desired for the combination, whether a flat geometry or a geometry comprising a specific doming, is guaranteed. This is because the shrinkage of the injected polymer is accompanied by a comparable shrinkage
of the encapsulating polymer, which cushions or absorbs a possible differential shrinkage of the photovoltaic cell, or
of the photovoltaic cell, when it is openwork.

In the latter case, an encapsulating polymer may not be employed and the cell simply bonded to the injected polymer, but such a use of encapsulating polymer for an openwork cell—as for a continuous cell—does not depart from the scope of the invention.

In a specific implementation, the face of the photovoltaic cell directed toward the injected polymer is also caused to adhere to an encapsulating polymer as defined above by its characteristics of thermal expansion and minimum melting point. The encapsulating polymer is then capable of forming a complete cushioning envelope—of differential thermal expansion—for the photovoltaic cell.

The encapsulating polymers adhering to the two faces of the cell may then be identical or different, provided that they satisfy the criteria defined above.

This specific implementation is recommended in the case of a continuous photovoltaic cell, in particular a rigid one, for which causing just the face directed away from the injected polymer to adhere to the encapsulating polymer may not be sufficient, in some cases, to cushion the differential shrinkage of the cell and to prevent a divergence with respect to the final shape desired for the combination obtained.

The base of the photovoltaic cell may
be distinct from the encapsulating polymer or, on the contrary,
constitute a portion at least thereof, the active face of the cell then being deposited directly on the encapsulating polymer. An example of such a base is a sheet of polyimide with a thickness of between 13 and 125 μm, preferably 20 and 30 μm.

Said injected (injectable) polymer is transparent or opaque and can consist of polymethyl methacrylate (PMMA) or the like. However, it is preferably a polycarbonate or equivalent and has a thickness of between 2 and 10 mm, in particular at most equal to 7 mm.

The base of the photovoltaic cell can be of metal or equivalent, is optionally openwork and has a thickness of between 25 and 500 μm, preferably between 75 and 250 μm, or of polymer, such as polyimide, with a thickness of between 13 and 125 μm. Examples thereof are a cell base made of
flexible steel with a thickness of 25 to 200 μm, preferably of 100 to 150 μm, or
rigid steel with a thickness of 100 to 500 μm, preferably of 175 to 225 μm.

The active face of the photovoltaic cell can be composed of a sheet of amorphous Si with a thickness of between 20 and 200 μm combined, for example, with a base of flexible metal or polymer, or of a sheet of crystalline Si with a thickness of between 100 and 300 μm combined, for example, with a rigid metal base, or of a thin layer of CIGS (CuInGaSe) or CdTe type combined with a flexible or rigid base of polymer, metal, and the like.

The encapsulating polymer is preferably composed of a sheet of polycarbonate, polyimide, poly(ethylene terephthalate), polypropylene, polyethylene, polyurethane or equivalent with a thickness of between 13 μm and 2 mm, preferably at most equal to 500 μm, adhering to one or both faces of the photovoltaic cell. Particularly preferably, the thickness of this sheet is at least equal to 250 μm, except when it forms the base of the photovoltaic cell, the thickness of which is advantageously at most equal to 125 μm and in particular between 20 and 30 μm.

According to other preferred characteristics of the structure of the invention:
the encapsulating polymer extends by at least 3% beyond the sides of the photovoltaic cell; thus, in the case of a cell formed of crystalline Si of 125×125 mm or 156×156 mm with a tolerance of ±0.5 mm, the extension would be at least 4.5 mm;
the injected polymer or the encapsulating polymer is tinted, provided that it is positioned behind the photovoltaic cell with respect to the sun; this measure makes it possible to screen out the solar radiation inside a vehicle or building without affecting the solar radiation received by the cell and to more or less conceal the cell from the view of the occupants of the vehicle or building;
the structure is transparent over a portion at least of its surface.

Moreover, a subject matter of the invention is a process for the manufacture of a structure as described above, in which, during the injection of said injected polymer, said photovoltaic cell is placed in the mold for injection of the polymer.

Moreover, the injection process makes it possible to obtain complex shapes, in particular domed shapes, of variable thicknesses over the extent of the composite structure, transparent parts and opaque parts, and the like.

Moreover, the measures of the invention (face of the photovoltaic cell directed away from the injected polymer caused to adhere to an encapsulating polymer, or openwork photovoltaic cell) guarantee the maintenance of these desired more or less complex shapes after cooling, the integrity of the photovoltaic cell on cooling and under living conditions, and good durability.

Another subject matter of the invention consists of a simple or multiple and monolithic or laminated window comprising a structure as described above. A multiple window denotes a window composed of several transparent substrates set apart from one another with interposition of a band of air or dry gas (presence of a desiccant). Each of these transparent substrates can be monolithic or laminated. A window is said to be simple if it comprises only one such transparent substrate.

The latter, when it is laminated, comprises said injected polymer connected, for example, to a transparent glass or plastic sheet via an intercalated adhesive, such as polyvinylbutyral or polyurethane.

Another subject matter of the invention is the application of a window described above for a ground transportation vehicle (in particular as motor vehicle roof), aerial transportation vehicle or water transportation vehicle, for the construction industry or for street furniture (bus shelter, telephone booth, display panel, and the like).

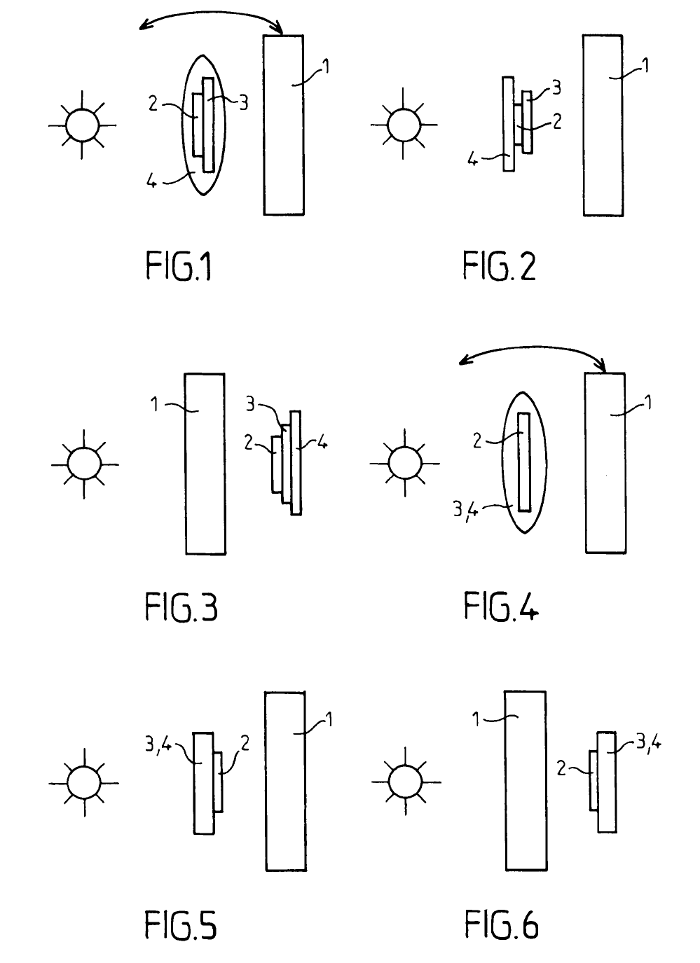

The invention is now illustrated by the following examples which refer to the appended FIGS. 1 to 6, diagrammatically representing six implementations of the composite structure of the invention.

The relative dimensions of the various constituent components of this structure are not observed but will be clarified in the continuation, if necessary.

The photovoltaic cell of FIG. 1 comprises an openwork base 3 of flexible steel of Invar type with a thickness of 125 μm or, alternatively, an openwork base 3 of rigid steel with a thickness of 200 μm.

The active face 2 of the cell consists of a sheet of amorphous silicon with a thickness of 20 to 200 μm, or alternatively of a sheet of crystalline silicon with a thickness of 100 to 300 μm, or also of a deposited body formed of thin photovoltaic layers of CIGS or CdTe or the like.

A cushioning envelope 4 of polyimide includes the whole of the photovoltaic cell. The thickness of the polyimide on each face of the cell is 25 μm. Alternatively, thicknesses of polycarbonate of 250 to 500 μm might be employed on each face of the cell.

The cushioning envelope extends beyond the periphery of the cell by 4.5 mm.

Contrary to the representation of FIG. 1, the sheet of polycarbonate 1 with a thickness of 4 mm is bonded by injection to the combination on the right-hand or left-hand side in the figure.

In the event of the laminated structure being intended for positioning to the right of the sun, as represented, the polycarbonate 1 may be tinted if it is bonded to the right of the cell in the figure. In the opposite case, such a characteristic would limit the solar radiation reaching the active face 2 of the cell.

In FIG. 2, the cushioning envelope 4 of FIG. 1 is replaced by a simple polymeric support 4 bonded to the active face 2. The nature and the thickness of the polymeric support 4 are identical to those of the parts of the cushioning envelope 4 of FIG. 1 bonded to each of the two faces of the cell.

The base 3 is of the type made of flexible steel mentioned above.

The active face 2 of the photovoltaic cell is of the type made of amorphous silicon or a thin layer of GIGS, CdTe, or the like, mentioned above.

The sheet of polycarbonate 1 is bonded on the right-hand side of the cell via the polymeric support 4. It may be tinted.

The composite structure of FIG. 3 is obtained by inverting the positioning of the constituents 1 and 4 of FIG. 2. The polymeric support 4 may be tinted.

In FIGS. 4 to 6, the base 3 of the cell is a cushioning sheet 4 of polyimide or polycarbonate identical to the polymeric support 4 of FIG. 2.

In FIG. 4, this base 3 is combined with another sheet with the same properties, with which it forms a cushioning envelope 4 similar to that of FIG. 1.

The sheet of polycarbonate 1 is bonded by injection on the right-hand or left-hand side of the cell. It may be tinted in the case of positioning to the right in FIG. 4.

In FIGS. 5 and 6, the active face 2 of the cell is bonded to the sheet of polycarbonate 1 via the polyimide or polycarbonate base 3, 4. The sheet of polycarbonate 1 or the polyimide or polycarbonate base 3, 4 respectively may be tinted in FIGS. 5 and 6 respectively.

1. A composite structure, comprising a photovoltaic cell adhering to an injected polymer, in which the photovoltaic cell exhibits an active face adhering to a base,
wherein
the photovoltaic cell is continuous and a face directed away from the injected polymer adheres to an encapsulating polymer with a linear thermal expansion coefficient which does not differ by more than 65% from that of the injected polymer and with a minimum melting point which allows the encapsulating polymer to withstand the injection of the injected polymer and which promotes adhesion to the injected polymer, or
the photovoltaic cell is openwork.

2. The structure of claim 1, wherein a face of the photovoltaic cell directed toward the injected polymer also adheres to the encapsulating polymer.

3. The structure of claim 1, wherein the base is distinct from the encapsulating polymer.

4. The structure of claim 1, wherein the base constitutes at least a portion of the encapsulating polymer.

5. The structure of claim 1, wherein the injected polymer is a polycarbonate or equivalent and has a thickness of between 2 and 10 mm.

6. The structure of claim 1, wherein the base of the photovoltaic cell is made of metal or equivalent and has a thickness of between 25 and 500 μm or is made of polymer with a thickness of between 13 and 125 μm.

7. The structure of claim 1, wherein the active face of the photovoltaic cell comprises a sheet of amorphous Si with a thickness of between 20 and 200 μm, or of a sheet of crystalline Si with a thickness of between 100 and 300 μm, or of a thin layer of CIGS (CuInGaSe) or CdTe type.

8. The structure of claim 1, wherein the encapsulating polymer comprises a sheet of polycarbonate, polyimide, poly(ethylene terephthalate), polypropylene, polyethylene, polyurethane or equivalent with a thickness of between 13 μm and 2 mm adhering to one or both faces of the photovoltaic cell.

9. The structure of claim 1, wherein the encapsulating polymer extends by at least 3% beyond the sides of the photovoltaic cell.

10. The structure of claim 1, wherein the injectable polymer or the encapsulating polymer is tinted, provided that the tinting is positioned behind the photovoltaic cell with respect to the sun.

11. The structure of claim 1, wherein the structure is transparent over at least a portion of its surface.

12. A process for manufacturing the structure of claim 1, comprising placing the photovoltaic cell in a mold for injection of the injected polymer during the injection of the injected polymer.

13. A window comprising the structure of claim 1.

14. An object comprising the window of claim 13 selected from the group consisting of a ground, aerial or water transportation vehicle, and street or exterior furniture.

15. The structure of claim 1, wherein the photovoltaic cell is continuous and its active face directed away from the injected polymer adheres to an encapsulating polymer with a linear thermal expansion coefficient which does not differ by more than 65% from that of the injected polymer and with a minimum melting point which allows the encapsulating polymer to withstand the injection of the injected polymer and which promotes adhesion to the injected polymer.

16. The structure of claim 1, wherein the photovoltaic cell is openwork.

17. The structure of claim 5, wherein the injected polymer has a thickness of between 2 and 7 mm.

18. The structure of claim 6, wherein the photovoltaic cell is openwork.

19. The structure of claim 6, wherein the base has a thickness of between 75 and 250 μm.

20. The structure of claim 8, wherein the sheet of polycarbonate, polyimide, poly(ethylene terephthalate), polypropylene, polyethylene, polyurethane or equivalent with a thickness of between 13 μm and 500 μm.
